(19) United States
(12) Patent Application Publication
(10) Pub. No.: US 2011/0267914 A1
(43) Pub. Date: Nov. 3, 2011

(54) SEMICONDUCTOR MEMORY DEVICE

(75) Inventors: Satoshi ISHIKURA, Osaka (JP); Norihiko Sumitani, Osaka (JP); Akira Masuo, Hyogo (JP)

(73) Assignee: Panasonic Corporation, Osaka (JP)

(21) Appl. No.: 13/181,996

(22) Filed: Jul. 13, 2011

Related U.S. Application Data
(63) Continuation of application No. PCT/JP2009/005712, filed on Oct. 28, 2009.

(30) Foreign Application Priority Data
Jan. 20, 2009 (JP) 2009-010236

(51) Int. Cl. G11C 7/06; G11C 7/00

(52) U.S. Cl. 365/208; 365/189.011

(57) ABSTRACT

Characteristics of both a memory cell and a peripheral circuit are degraded due to random variations, and a defective characteristic occurs in a combination of components having a substantially worst characteristic at a macro level. To solve this problem, a selector is provided between the memory cell and the peripheral circuit so that a positive phase and a negative phase of bit lines are switched at a portion where the defective characteristic occurs. Alternatively, the combination of a bit line and a sense amplifier is switched between adjacent data input/output sections, for example. In other words, the defective characteristic is repaired or corrected by canceling the combination of worst components.

### CROSS-REFERENCE TO RELATED APPLICATIONS

This is a continuation of PCT International Application PCT/JP2009/005712 filed on Oct. 28, 2009, which claims priority to Japanese Patent Application No. 2009-010236 filed on Jan. 20, 2009. The disclosures of these applications including the specifications, the drawings, and the claims are hereby incorporated by reference in their entirety.

### BACKGROUND

The present disclosure relates to techniques of repairing semiconductor memory devices, and more particularly, to techniques of repairing or correcting a defective characteristic of a memory cell which occurs due to random variations caused by miniaturization.

Memory cells occupy a large area of a large scale integration (LSI) circuit, and therefore, there is a strong demand for a reduction in the area. However, semiconductor devices fabricated by microfabrication technology meeting 45 nm or less design rules have encountered a significant problem that random variations in characteristics of a transistor increase due to a reduction in device size, leading to variations in characteristics of a static random access memory (SRAM) cell.

A device variation (ΔVt) is given by ΔVt=Pelgrom's coefficient×(1/SQRT(Wg×Lg)) where Wg is the gate width of the device and Lg is the gate length of the device. If Pelgrom's coefficient is the same, then when the device size is reduced by a factor of 0.7 by device scaling from one process technology generation to the next, the device variation increases by a factor of about 1.4. Memory cells have a write characteristic, a noise margin characteristic during read operation, and a cell current characteristic during read operation. When the cell area is reduced to track scaling trends, it is considerably difficult to ensure the characteristics of memory cells at a mega-bit level, which is a significant problem in the field of memory technology.

Firstly, a conventional one-port SRAM cell will be described with reference to FIG. 21. The one-port SRAM cell includes: a word line 100 which is used to control the gates of access transistors 105 and 106 in the SRAM cell; a pair of bit lines 101 and 102 which are used to transfer write data or read data of the SRAM cell, or are used to transfer positive-phase data and negative-phase data which are inverse to each other; internal nodes 103 and 104 which hold data of the SRAM cell; the access transistors 105 and 106 whose gates are controlled by the word line 100 to electrically connect the bit lines 101 and 102 to the internal nodes 103 and 104, respectively, during read/write operation; P-type MOS transistors 107 and 108; and N-type MOS transistors 109 and 110. One of the P-type MOS transistors 107 and 108 and one of the N-type MOS transistors 109 and 110 are turned on to hold the potential of a corresponding one of the internal nodes 103 and 104.

Next, a two-port SRAM cell including a single read bit line will be described with reference to FIG. 22. The two-port SRAM cell includes: a write word line 111 which is used to control the gates of write access transistors 116 and 117 during write operation; a read word line 112 which is used to control the gate of a read access transistor 122 during read operation; a pair of write bit lines 113 and 114 which transfer positive-phase data and negative-phase data which are inverse to each other to the SRAM cell during write operation; a read bit line 115 which transfers data read from the SRAM cell during read operation; the write access transistors 116 and 117 which electrically connect the write bit lines 113 and 114 to the internal nodes 103 and 104, respectively, during write operation; a read drive transistor 120 which electrically receives the internal node 104 at the gate; and the read access transistor 122 which connects the read bit line 115 to the drain of the drive transistor 120. The cell is configured to temporarily receive and read the potential of the internal node at the gate of the transistor 120. Therefore, during simple read operation in which only the read word line 112 is active, i.e., there is no simultaneous access from the read and write ports, the potential level of the internal node is not interfered by the bit line, and a read noise margin-free cell characteristic is provided. Therefore, in order to increase a cell current to achieve high-speed operation, the gate width of the read port transistor can be easily increased. The SRAM cell has recently attracted attention not only as a two-port memory cell but also a one-port memory cell mainly in high-speed and low-voltage applications (see L. Chang et al., “Stable SRAM Cell Design for the 32 nm Node and Beyond,” Symposium on VLSI Technology Digest of Technical Papers, pp. 128-129, 2005 (referred to as Non-Patent Document 4), and Y. Morita et al., “An Area-Conscious Low-Voltage-Oriented 8T-SRAM Design Under DVS Environment,” Symposium on VLSI Circuits Digest of Technical Papers, pp. 256-257, 2007 (referred to as Non-Patent Document 8)).

FIGS. 23A and 23B show a memory circuit in which data is read from the memory cell of FIG. 21 using a differential sense amplifier 124. When data is written to the memory cell, one of complementary bit lines 101 and 102 is driven to a low voltage by one of complementary bit line drivers 125 and 126. During read operation, the sense amplifier 124 amplifies the potential difference between the bit lines 101 and 102 at a timing when a sense amplifier activation signal 128 is activated, thereby reading data stored in the memory cell.

FIG. 24 shows a memory circuit in which data is read from the memory cell having a single bit line of FIG. 22. A logic operation amplifier circuit 127 which is not of the differential amplification type amplifies the potential of the read bit line 115 to read data stored in the memory cell. Compared to the read operation of the SRAM cell having two bit lines of FIG. 23A which is performed using a differential sense amplifier, the bit line amplitude needs to be increased to about a logic threshold for logic circuit operation. Therefore, there is a technique of providing hierarchical bit lines on the read port side to achieve high-speed operation without read sense amplifier operation (see U.S. Pat. No. 6,014,338 (referred to as Patent Document 1), Japanese Patent Publication No. 2004-47003 (referred to as Patent Document 2), W. H. Henkels, et al., “A 500 MHz 32-Word×64-Bit 8-Port Self-Resetting CMOS Register File and Associated Dynamic-to-Static Latch,”

Symposium on VLSI Circuits Digest of Technical Papers, pp. 41-42, 1997 (referred to as Non-Patent Document 3), R. Joshi et al., “6.6+ GHz Low Vmin, read and half select disturb-free 1.2 Mb SRAM,” Symposium on VLSI Circuits Digest of Technical Papers, pp. 250-251, 2007 (referred to as Non-Patent Document 5), and L. Chang et al., “A 5.3 GHz 8T-SRAM with Operation Down to 0.41V in 65 nm CMOS,” Symposium on VLSI Circuits Digest of Technical Papers, pp. 252-253, 2007 (referred to as Non-Patent Document 6)).

FIG. 25 is a circuit diagram mainly showing a local amplifier for hierarchical bit lines in a two-column arrangement. In a hierarchical bit line technique, as shown in FIG. 25, a memory cell array is divided into groups of a plurality of memory arrays along the bit line direction (groups of 16 cells in FIG. 25). Read bit lines in each memory array group are connected together by a local read bit line 131. A plurality of the local read bit lines 131 arranged in the bit line direction are connected via a local amplifier 129 to a global read bit line 132. The local amplifier 129 includes a PMOS transistor 130, a positive-phase precharge control signal line 133, a negative-phase precharge control signal line 134, and a negative-phase column address select signal line 135.

For example, if there are 512 memory cells along the bit line direction in the memory cell array, a load on a local bit line is reduced to 16/512=1/32 in this example where the memory cell array is divided into groups of 16 memory cells, whereby high-speed read operation can be performed. Also, all delay paths which determine the access time perform logic operation without using a sense amplifier, and read data is determined by the drive capability of each memory cell itself. Therefore, it is not necessary to delay the timing of activation of the sense amplifier to such an extent that the sense amplifier can fail to perform differential read operation without error. The operating speed is determined by the limit of the cell current of the memory cell. Therefore, read operation can advantageously be performed at the high speed limit.

In the 8-transistor SRAM cell including a single bit line of FIG. 22, data is read by receiving the discharge level of a bit line of a memory cell at the amplifier circuit 127 of FIG. 24, the gate of the PMOS transistor 130 of FIG. 25, etc. in a data output section without using a differential sense amplifier. In the single bit line read structure, when high-side data is read using the read bit line, a state in which the read bit line potential is held at Hi-z is read, and therefore, erroneous read operation is likely to occur due to a leakage current to the read bit line. In particular, in the case of a two-port cell, the risk of erroneous operation is dramatically increased due to not only a simple cut-off leakage current of a transistor but also a leakage current (hereinafter referred to as an erroneous read current) which occurs in a weak on state caused by simultaneous operation from both read and write ports. FIG. 26 is an image diagram showing a waveform in the case of the arrangement of FIG. 25. Erroneous read operation occurs due to a drop in the bit line potential caused by a leakage current although the leakage current is delayed from a normal low read cell current. To solve this problem, a circuit technique has been proposed in which read operation is ended before the local amplifier 129 responds to output erroneous read data, i.e., between normal low read operation and erroneous read operation, for example (see S. Ishikura et al., “A 45 nm 2port 8T-SRAM using hierarchical replica bitline technique with immunity from simultaneous R/W access issues,” Symposium on VLSI Circuits Digest of Technical Papers, pp. 254-255, 2007 (referred to as Non-Patent Document 7)).

To achieve higher definition and higher performance of digital devices in the future, there is a demand for system LSIs which perform signal processing at even higher speed. However, it is inherently not possible to reduce the threshold voltage of transistors because of a limitation on the off-leakage current. In this situation, the overdrive capability is reduced due to the decrease of the power supply voltage, and in addition, variations in transistor characteristics tend to be exacerbated due to the progress of miniaturization. Therefore, even when a state-of-the-art process technique is employed, the cell current tends to be decreased, so that it considerably difficult to increase the speed. When the cell current is small, then if the sense amplifier activation signal is activated at an earlier timing in order to achieve a shorter access time, erroneous operation occurs in the case of a combination of a cell having a small cell current and a sense amplifier having a large offset amount because the sense amplifier itself has an offset due to variations in transistor characteristics (see FIGS. 2A and 2B).

To solve this problem, a circuit technique has been proposed in which a circuit is operated at the speed limit of the cell current and it is not necessary to apply a sense amplifier activation signal (see N. Verma, et al., “A High-Density 45 nm SRAM Using Small-Signal Non-Strobed Regenerative Sensing,” ISSCC Digest of Technical Papers, pp. 380-381, Feb. 2008 (hereinafter referred to as Non-Patent Document 2)).

As a practical solution, conventionally, a redundancy repair circuit (shown in FIG. 27) having a function of repairing or correcting a defective pattern is used to repair or correct, by a redundancy scheme, defective speed which occurs when a circuit is designed so that the sense amplifier is activated at an earlier timing. In FIG. 27, the redundancy repair circuit includes a normal circuit 140, a redundant circuit 141, and a defective memory cell 142. Reference characters 143, 144, 145, and 146 indicate shift redundancy signals 0-3. Here, it is assumed that a memory section including the defective memory cell 142 (or a memory portion including the memory cell 142 having defective speed) and a peripheral circuit including a sense amplifier are unused, and redundancy repair is performed using the previously provided redundant circuit 141. Redundancy repair is achieved by an address comparison scheme in which addresses are sequentially compared and a redundant circuit is used only during access to a defective address, a shift redundancy scheme in which a defective portion is skipped as an unused state as shown in FIG. 27, etc.

As miniaturization progresses, it becomes more difficult to perform read/write operation on memory cells. To overcome this problem, various characteristic assist techniques of facilitating cell operation have been proposed. Most of the techniques are directed to control of the potentials of main nodes, such as the source potential of a memory cell latch, the potential of a word line, etc., as described below. This is because when SRAM macros are used as a library, the macros are more easily used on a chip if the number of power supply separations is smaller, and particularly, when the same power supply as that of a peripheral logic portion, such as a standard cell etc. is used, erroneous operation caused by a potential difference, etc., can be reduced to a greater extent.

FIG. 28 shows a conceptual circuit configuration which provides a write assist technique of facilitating write operation by slightly decreasing the potential of a source potential node 160 of a memory cell latch inverter during write operation. In the write assist technique, an intermediate potential is generated by resistive division of transistors 161, and is used. The write assist intermediate potential generation transistors 161 in this case make a source potential supply circuit for the memory cell latch inverter. Alternatively, there is a technique of generating a potential using capacitive coupling. However, this technique has the same tendency for problems with variations in a generated potential described below, as miniaturization progresses.

FIG. 29 shows a conceptual circuit configuration of a word line potential control technique. According to the word line potential control technique, in a word line driver circuit including a row decoder 162, the high level of a word line 100 which occurs when a PMOS transistor 163 in the row decoder buffer is turned on is slightly lowered by a small NMOS on-state transistor (pull-down transistor) 164 to generate a desired word line potential (see M. Yabuuchi, et al., “A 45 nm Low-Standby-Power Embedded SRAM with Improved Immunity Against Process and Temperature Variations,” ISSCC Digest of Technical Papers, pp.326-327, Feb. 2007 (referred to as Non-Patent Document 1)).

On the other hand, there is a known technique of repairing a high-resistive defective cell without using a redundant circuit (see Japanese Patent Publication No. 2004-303343 (referred to as Patent Document 3)).

However, the above conventional techniques have the following problems which may be encountered as the progress of miniaturization continues.

The technique of Non-Patent Document 2 has a disadvantage that the area significantly increases compared to a simple inverter latch type sense amplifier. Also, although the speed limit which is determined by the cell current can be achieved, an operating speed which exceeds the cell current limit cannot be achieved.

The technique employing a redundant memory cell or a redundant peripheral circuit is, of course, accompanied by a proportionate increase in area. In particular, if it is desired to significantly increase the operating speed by repairing a large number of defects within a single macro, a number of redundant circuits corresponding the number of repaired portions need to be provided. If a large number of defective bits can be repaired by a redundancy scheme, the limit of design of memory cells is relaxed, so that a small-size transistor, which has large variations, can be used to provide a high-speed memory macro having a small cell area. In this case, however, it is necessary to provide a sufficient number of redundant circuits such that a large number of bits can be repaired.

For the above characteristic assist technique, the present inventors have found that as miniaturization progresses, the sizes of peripheral circuits as well as memory cells are reduced, so that variations in the potential generation level of the assist circuit tend to be exacerbated, and therefore, it is necessary to take measures against the variations in the potential generation level of the assist circuit as well as variations in memory cell characteristics. It is also necessary to increase the area or design a complicated circuit in order to reduce the variations in memory cell characteristics and the variations in the generation potential of the assist circuit (hereinafter referred to as assist potential variations). Specifically, in the conventional art, it is necessary to use redundant circuits, provide a function of trimming and adjusting generated intermediate potentials separately, etc., as is similar to the case of defects caused by a fabrication process (hereinafter also referred to as fabrication defects).

Redundancy repair circuits including redundant circuits have a problem that it is difficult to use the redundant cells in redundancy repair of a defective characteristic occurring after burn-in. Specifically, unless redundant memory cells are being operated even during burn-in, burn-in stresses corresponding to two values 0 and 1 stored by the redundant memory cells cannot be applied to the redundant memory cells.

If the application of uniform stress is abandoned in view of the frequency of occurrence, there is a risk that the test escape rate increases to reduce the reliability. If a circuit for applying stress is added in order to avoid such a problem, the addition of the circuit leads to an increase in area, the need of a complicated circuit which performs a special mode control, etc.

Patent Document 3 describes a technique of changing the order of operation of select circuits in a page mode operation, thereby repairing a high-resistive defective cell which has a decreased read speed. Patent Document 3 does not teach or suggest the random variation problem and is not applicable to memory circuits which perform random access operation.

### SUMMARY

A semiconductor memory device according to a first aspect of the present disclosure includes a memory cell, a differential sense amplifier, a positive-phase bit line and a negative-phase bit line connected to the memory cell, and a selector circuit configured to select electrical connections between the positive-phase and negative-phase bit lines and two inputs of the differential sense amplifier, i.e., determine which of the positive-phase and negative-phase bit lines is electrically connected to which of the two inputs of the differential sense amplifier.

According to a second aspect of the present disclosure, the semiconductor memory device of the first aspect may further include a circuit configured to invert write data based on a control signal for controlling the selector circuit configured to select the positive and negative phases of the bit lines.

According to a third aspect of the present disclosure, the semiconductor memory device of the first aspect may further include a circuit configured to invert data output from the differential sense amplifier based on a control signal for controlling the selector circuit configured to select the positive and negative phases of the bit lines.

A semiconductor memory device according to a fourth aspect of the present disclosure includes a plurality of memory cells, a plurality of peripheral circuits, and a selector circuit configured to electrically connect any of the plurality of memory cells to any of the plurality of peripheral circuits. The electrical connection relationship between any of the plurality of memory cells and any of the plurality of peripheral circuits is changed based on a control signal for controlling the selector circuit.

According to a fifth aspect of the present disclosure, in the semiconductor memory device of the fourth aspect, the plurality of peripheral circuits may be a circuit including a differential sense amplifier.

According to a sixth aspect of the present disclosure, in the semiconductor memory device of the fourth aspect, the plurality of memory cells may be of a single bit line read type.

According to a seventh aspect of the present disclosure, the semiconductor memory device of the sixth aspect may further include a hierarchical bit line structure.

According to an eighth aspect of the present disclosure, in the semiconductor memory device of the fourth aspect, the plurality of peripheral circuits may be a source potential supply circuit for a memory cell latch inverter.

According to a ninth aspect of the present disclosure, in the semiconductor memory device of the fourth aspect, the plurality of peripheral circuits may be a word line driver circuit.

According to a tenth aspect of the present disclosure, the semiconductor memory devices of the first to ninth aspects may further include a non-volatile element, such as a fuse element etc., which is configured to set a select state of the selector circuit.

According to an eleventh aspect of the present disclosure, in the semiconductor memory devices of the first to ninth aspects, only a single input pin configured to control the selector circuit may be provided for each macro.

According to a twelfth aspect of the present disclosure, in the semiconductor memory devices of the first to ninth aspects, a plurality of input pins configured to control the selector circuit may be provided for each macro.

According to the first aspect of the present disclosure, a defective characteristic, such as insufficient speed etc., caused by a combination of a memory cell having a small cell current and a sense amplifier having a large offset, which are caused by random variations, is repaired or corrected by switching the positive and negative phases of the bit lines to change the combination to obtain a configuration that the offset of a sense amplifier is advantageous for a side where the read current of a worst cell is small. Compared to a conventional redundancy repair scheme employing a redundant circuit, a redundant circuit is not used. Therefore, in particular, when a large number of defects are repaired in one macro, the area can be reduced. As a secondary effect, access is sped up by setting a sense amplifier activation timing earlier, and the area is reduced by the reduction of the memory cell area. The first aspect of the present disclosure is also applicable to random access memory devices, first-in first-out memory devices, and page-mode memory devices.

Also, for a defective characteristic occurring in a reliability burn-in test, the redundancy repair scheme employing a redundant cell has disadvantages that data stored in the redundant cell cannot be alternately switched between 0 and 1 during burn-in, or a special burn-in mode circuit is required for the switching. The device of the first aspect of the present disclosure does not have such disadvantages, and has an advantage that burn-in stress can be applied so that stored data 0 and 1 are alternately applied. According to the second aspect of the present disclosure, the read data inversion phenomenon occurring when the first aspect of the present disclosure is applied can be effectively corrected within a macro. In other words, the positive or negative logic of read data can be corrected within a macro without performing a complicated process, such as inversion of the read data based on a repair address by a logic circuit provided outside the macro, etc. Also, compared to the third aspect of the present disclosure, a logic circuit related to the third aspect of the present disclosure is not inserted into a memory cell read system, and therefore, the access time can advantageously be sped up.

According to the third aspect of the present disclosure, the read data inversion phenomenon occurring when the first aspect of the present disclosure is applied can be effectively corrected within a macro. Also, compared to the second aspect of the present disclosure, there are advantages when a test is performed. The data hold potential of a memory cell is invariable before and after repair. Therefore, in the second aspect of the present disclosure, when a checker pattern is externally applied, the relationship between the hold potentials 0 and 1 is changed at a portion where write data is inverted, so that a desired potential relationship cannot be set using a test pattern which is expected to provide different potentials of adjacent cells, and such a defect reduces the quality of the test. According to the third aspect of the present disclosure, the first aspect of the present disclosure can be applied without producing such a defect.

In the semiconductor memory device of the fourth aspect of the present disclosure, a defective characteristic caused by random variations can be repaired by switching component combinations without using a redundant circuit (characteristic repair). The fourth aspect of the present disclosure is also applicable to random access memory devices, FIFO memory devices, and page-mode memory devices. The device operates during burn-in. However, for a defective characteristic occurring after burn-in, the redundancy repair scheme employing a redundant cell has disadvantages that data stored in the redundant cell cannot be alternately switched between 0 and 1 during burn-in, or a special burn-in mode circuit is required for the switching. The device of the fourth aspect of the present disclosure does not have such disadvantages, and has an advantage that burn-in stress can be applied so that stored data 0 and 1 are alternately applied.

The semiconductor memory device of the fifth aspect of the present disclosure can obtain the advantages of the fourth aspect of the present disclosure for defective read speed which occurs due to a relationship between a worst cell having a small cell current and a worst amplifier having a large offset amount. In particular, an insufficient speed problem which occurs a relationship between a worst cell having a reduced cell current caused by transistor random variations and a sense amplifier having a large offset caused by the transistor random variations, can be overcome. Compared to a redundancy repair scheme employing a redundant circuit, in particular, when a large number of defects are repaired in one macro, the area can be reduced. As a secondary effect, access is sped up by setting a sense amplifier activation timing earlier, and the area is reduced by the reduction of the memory cell area. The fifth aspect of the present disclosure is also applicable to random access memory devices, first-in first-out memory devices, and page-mode memory devices, etc.

The semiconductor memory device of the sixth aspect of the present disclosure can repair or correct defective read speed which occurs due to a relationship between a worst cell having a small cell current and a worst amplifier having a large difference between a logic threshold and a precharge level, and in addition, overcomes the erroneous read problem described in the BACKGROUND section. Also, another erroneous read problem that a defect which occurs due to a relationship between a worst cell having a large leakage current and a worst amplifier having a small difference between a precharge level and a logic threshold can be repaired or corrected without using a redundant memory cell or a redundant sense amplifier (characteristic repair), resulting in stable memory operation and a higher yield.

The semiconductor memory device of the seventh aspect of the present disclosure has a considerably small capacity of a local bit line, and therefore, has advantages similar to those of the sixth aspect of the present disclosure in a hierarchical bit line structure in which erroneous read operation is likely to occur compared to a non-hierarchical bit line read circuit. Also, if switch repair is performed on a local bit line-by-local bit line basis by utilizing a configuration in which a memory array space is divided along the bit line direction, the risk of occurrence of a new defective characteristic caused by the switching can be reduced.

The semiconductor memory device of the eighth aspect of the present disclosure can repair or correct a defective characteristic in an assist circuit which controls the source potential of a memory cell latch inverter, without using a redundant cell or a redundant word line driver circuit. Specifically, the device can repair or correct a defective characteristic of a memory cell which occurs due to variations in the VDDM level of a write assist circuit which facilitates data write to the memory cell, where the source potential (VDDM) of a memory cell latch inverter is set to be lower than a power supply voltage. For example, by changing a relationship between a cell having a poor write characteristic and VDDM having a high potential level, which are caused by random variations, a defective write characteristic can be repaired or corrected. Also, a defect which occurs in a memory cell which has a poor retention characteristic and in which stored data disappears when VDDM decreases excessively, in the presence of a VDDM generation circuit which produces a low potential, can be repaired or corrected. Also, in a read assist circuit which improves the data hold capability of a memory cell by setting the source potential VDDM of a memory cell latch inverter to be higher than a power supply voltage during read operation, a defective characteristic can be repaired or corrected by changing a relationship between variations of the memory cell and VDDM.

The semiconductor memory device of the ninth aspect of the present disclosure can repair or correct a defective characteristic of a memory cell which occurs due to variations in a write pulse width caused by a word line driver circuit, variations in a word line level of a read assist circuit which ensure a noise margin characteristic, where a word line is set to a voltage slightly lower than a power supply voltage, or variations of the memory cell. Specifically, the defective characteristic is repaired or corrected by changing and avoiding a relationship between a cell having a poor noise margin characteristic and a word line driver having a high potential level, which are caused by random variations, or a relationship between a cell having a poor write characteristic and a word line driver having a low potential level, which are caused by random variations. Because a redundant cell and a redundant word line driver circuit are not used, the area can be reduced.

The semiconductor memory device of the tenth aspect of the present disclosure is the semiconductor memory devices of the first to ninth aspects of the present disclosure in which data for generating a selector control signal for repairing a defect found by a test is previously written to a non-volatile element, such as a fuse etc., whereby a selector circuit is set to a desired state when the device is turned on, so that the defective device can be repaired and changed to a non-defective product.

The semiconductor memory device of the eleventh aspect of the present disclosure is the semiconductor memory devices of the first to ninth aspects of the present disclosure which can effectively carry out the defective characteristic repair or correction technique of the present disclosure while reducing the risk of occurrence of a defective characteristic which may occur again in a different combination when all recombinations are uniformly made on an entire chip. Also, if recombination is performed based on pass/fail determination at a macro level, the amount of repair address information handled can be reduced, resulting in an advantage that the repair technique can be easily performed.

The semiconductor memory device of the twelfth aspect of the present disclosure is the semiconductor memory devices of the first to ninth aspects of the present disclosure in which information input through a plurality of pins is decoded, and therefore, a plurality of defective characteristics can be repaired or corrected within one macro. By limiting a region where the switch process is performed to a region in the vicinity of a defective portion, the risk of occurrence of another defective characteristic which may occur after recombination can be reduced.

### BRIEF DESCRIPTION OF THE DRAWINGS

FIG. 1 is a circuit diagram showing characteristic repair according to a first embodiment in which the positive and negative phases of bit lines are switched (positive/negative switch).

FIGS. 2A and 2B are conceptual diagrams for describing a conventional problem.

FIG. 2C is a conceptual diagram for describing the characteristic repair by the positive/negative switch of bit lines of the first embodiment.

FIG. 3A is a diagram showing a conventional relationship between sense amplifier operation timings and bit line potentials.

FIG. 3B is a diagram for describing timings after the positive/negative switch of bit lines.

FIG. 4 is a diagram showing a configuration in which switch repair is simultaneously performed on a macro-by-macro basis in the first embodiment.

FIG. 5 is a diagram showing a combination of the first embodiment and a conventional redundancy repair circuit.

FIG. 6 is a diagram showing a configuration of a circuit in which write data is inverted in the bit line positive/negative switch of the first embodiment.

FIG. 7 is a diagram showing a configuration in which write data is output from a sense amplifier before being inverted in the bit line positive/negative switch of the first embodiment.

FIG. 8 is a diagram schematically showing switching of data input/output sections between adjacent bit lines in a second embodiment.

FIG. 9 is a circuit diagram showing switching of data input/output sections between adjacent bit lines in the second embodiment, where a write circuit section is also shown.

FIG. 10 is a circuit diagram showing switching of sense amplifiers between adjacent bit lines in the second embodiment.

FIG. 11A is a conceptual diagram for describing a conventional problem.

FIG. 11B is a conceptual diagram for describing switch repair in the case of a single bit line in a third embodiment.

FIG. 12 is a diagram showing a configuration of switch repair in the case of a single bit line in the third embodiment.

FIG. 13 is a diagram showing a circuit configuration in which all columns are switched on a local amplifier-by-local amplifier basis in the case of a single bit line in the third embodiment.

FIG. 14 is a diagram showing a configuration in which switch repair is applied to a write assist circuit in a fourth embodiment.

FIG. 15 is a first diagram showing a configuration in which switch repair is applied to a read assist circuit in the fourth embodiment.

FIG. 16 is a second diagram showing a configuration in which switch repair is applied to a read assist circuit in the fourth embodiment.

FIG. 17 is a diagram showing a configuration in which a control signal for switch repair is shared by all mounted macros in a fifth embodiment.

FIG. 18 is a diagram showing a configuration in which a control signal for switch repair is controlled in macros separately in the fifth embodiment.

FIG. 19 is a diagram showing a configuration in which a plurality of control signals for switch repair are provided for respective macros in the fifth embodiment.

FIG. 20 is a diagram showing a configuration in which a control signal for switch repair is supplied via a scan flip-flop in the fifth embodiment.

FIG. 21 is a circuit diagram showing a conventional one-port memory cell.

FIG. 22 is a circuit diagram showing a conventional two-port memory cell.

FIG. 23A is a diagram showing a configuration of a known read circuit for the one-port memory cell of FIG. 21.

FIG. 23B is a circuit diagram of a known differential sense amplifier in FIG. 23A.

FIG. 24 is a diagram showing a configuration of a known read circuit for the two-port memory cell of FIG. 22.

FIG. 25 is a diagram showing a configuration of a conventional hierarchical single-bit-line read circuit.

FIG. 26 is a diagram for describing timings of normal read operation and erroneous read operation in the configuration of FIG. 25.

FIG. 27 is a diagram showing a configuration of a conventional redundancy repair circuit employing a redundant circuit.

FIG. 28 is a diagram showing a configuration of a conventional inverter latch potential drop type write assist circuit.

FIG. 29 is a diagram showing a configuration of a conventional word line potential drop type read assist circuit.

### DETAILED DESCRIPTION

Embodiments of the present disclosure will be described in detail hereinafter with reference to the accompanying drawings.

### First Embodiment

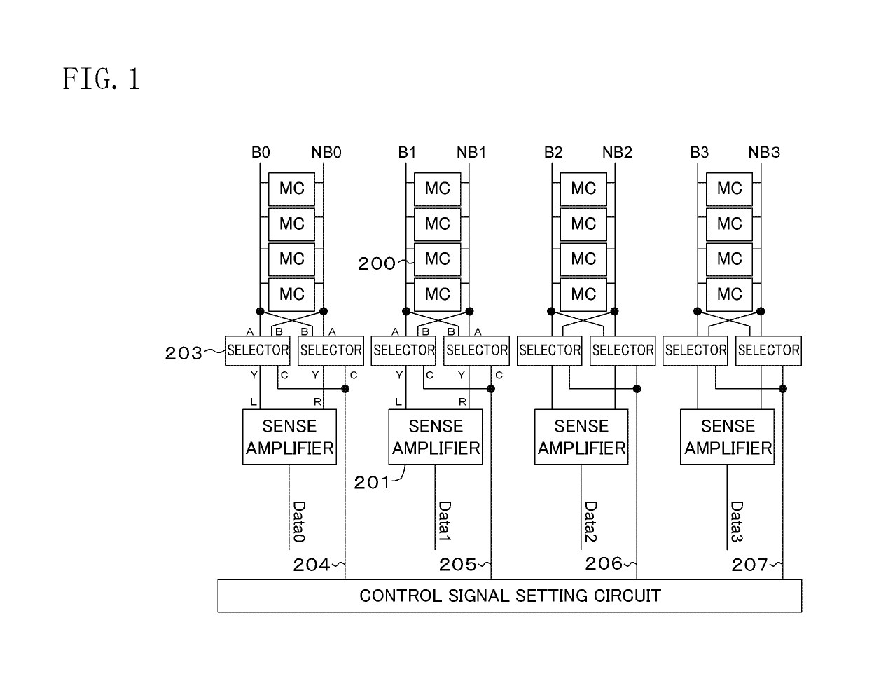

FIG. 1 shows an example in which the present disclosure is applied to a circuit including an SRAM memory array. In FIG. 1, selectors 203 are provided between memory cells 200 and sense amplifiers 201. Each selector 203 outputs A to Y when C=high and B to Y when C=low. Selector control signals 204-207 are normally set to C=high.

Here, it is assumed that a worst memory cell 200 that has been determined to be defective by a low-voltage test is located in a connection region to B1/NB1 of the second column from the left. If the control signal 205 of the control signals 204-207 is controlled to C=low so that the connection between the memory cell and the sense amplifier is reversed compared to the normal connection, the selector 203 outputs an input of the B side to Y. As a result, the inputs of the left and right sides of the sense amplifier 201 are switched, so that data stored by the worst memory cell 200 is output to the sense amplifier 201.

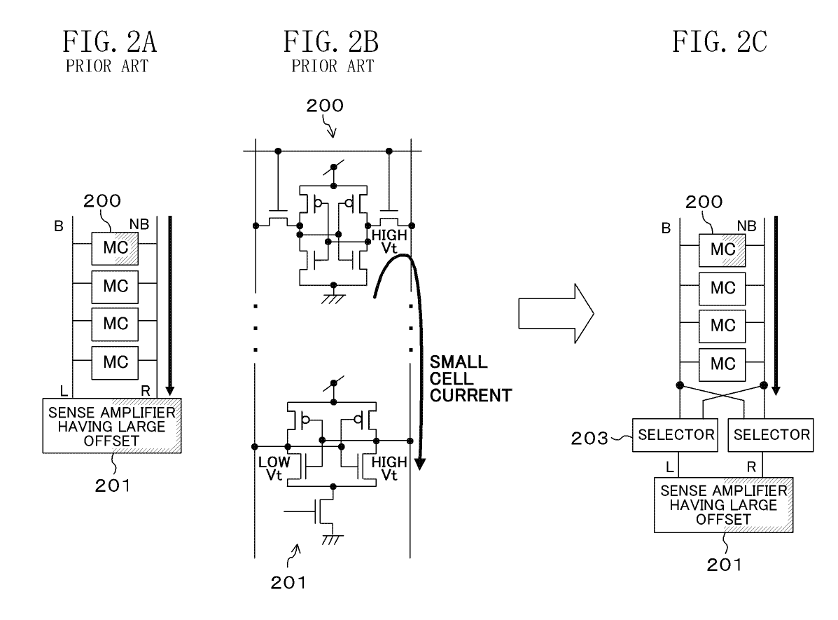

As described above in the BACKGROUND section with reference to FIGS. 2A and 2B, a technique of repairing or correcting defective read speed which is caused by a combination of a worst memory cell 200 having a low bit line discharge speed and a worst sense amplifier 201 having a large offset amount, will be described. Here, it is assumed that, as shown in FIGS. 2A and 2B, a transistor located on the right side of each component has a high Vt.

The capacity of a memory included in a system LSI fabricated by microfabrication is, for example, about 10 megabits. In order to ensure a satisfactory chip yield, a statistical design assurance of about 6σ is required. The total number of sense amplifiers included in each macro corresponds to about 4σ. Therefore, in recent years, SRAMs have been statistically designed, taking it into consideration to some extent that the encounter probability of components (memory cells and sense amplifiers) having a characteristic close to ends (skirts) of a statistical normal distribution is low.

In order to decrease the size of memory cells to reduce the cost of LSIs, not only design rules are reduced by miniaturization efforts, but also the size of transistors used needs to be reduced. However, the reduction in transistor size leads to an increase in random variations of transistors. As a result, a chip which does not satisfy the operating voltage range occurs, so that a characteristic yield decreases.

In the sense operation of a memory, charge is discharged from a precharged state of VDD to a low potential by a memory cell, and a sense amplifier is activated at a predetermined sense amplifier activation timing, thereby amplifying the potential difference between a positive-phase bit line and a negative-phase bit line. In order to speed up the access time, the sense amplifier activation timing is preferably set as early as possible.

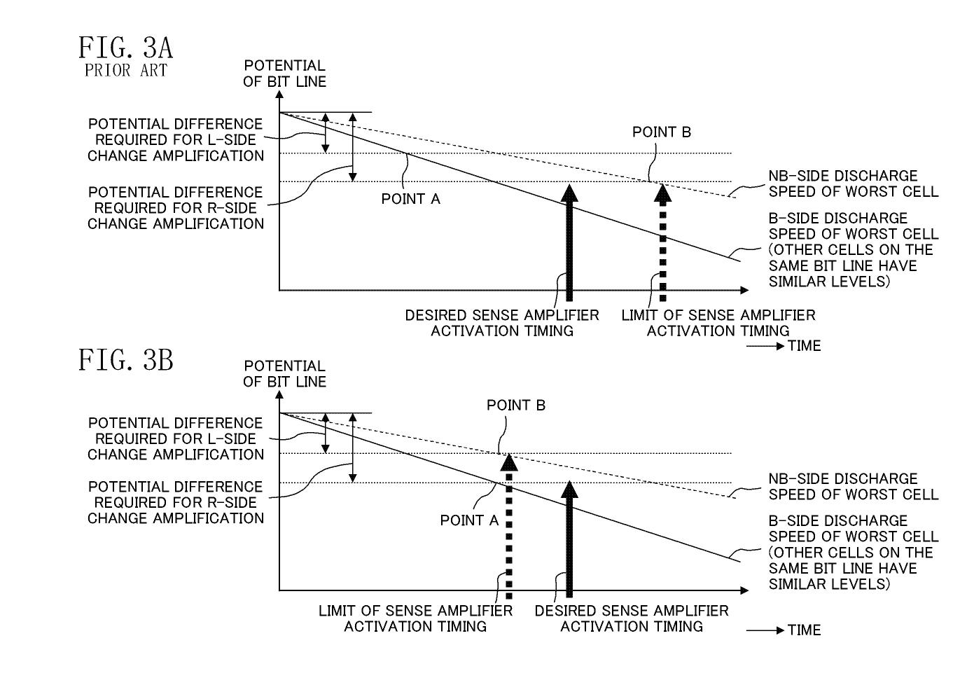

FIG. 3A is a diagram showing a conventional relationship between sense amplifier operation timings and bit line potentials. Assuming that it is necessary to discharge a bit line potential to some extent because of the influence of noise or in order to complete sense operation within a predetermined activation time, an offset occurs in a required potential level between the left and right sides due to random variations. In order to cancel the sense amplifier offset amount to achieve normal operation, a larger bit line amplitude amount is required when the low potential is input to the right (R) side than when the low potential is input to the left (L) side. If the discharge operation is performed at a timing later than the desired sense amplifier activation timing, a bit line amplitude sufficient to cancel the offset amount of the sense amplifier is not obtained, resulting in defective operation.

To solve this problem, the present disclosure provides a configuration that the left and right component combinations of the memory cell 200 and the sense amplifier 201 can be switched using the selectors 203 as shown in FIG. 2C. As a result, as shown in FIG. 3B, a transistor having a high Vt on the right side of a memory cell having a low discharge speed is a worst amplifier, but is connected to a terminal on the left side which is advantageous for read operation in terms of offset, and therefore, even if sense operation is preformed at the desired sense amplifier activation timing, defective read operation caused by speed does not occur. Moreover, the left-side access transistor having a large cell current of a worst cell is connected to the R-side input having a large required offset amount. Therefore, as can be seen by comparison between FIGS. 3A and 3B, an activation timing limit (point B) determined by the worst cell and the worst sense amplifier is improved, although the point B is delayed from the timing of the original point A. Because the access time is determined by a path which passes through a component having a lowest operating speed, the memory macro can be operated at high speed.

This technique is based on the following fact. The defect of interest is caused by random variations, and defects occur at a rate of as low as several defects per several tens of megabits. Therefore, even if a defective component is replaced with a component adjacent to the defective portion, the statistical probability that a defect still occurs is considerably low.

For example, it is assumed that 6σ and 4σ are required for memory cells and sense amplifiers, respectively, in view of mount capacity, and actually, a defect occurs when memory cells having variations corresponding to 5σ encounter sense amplifiers having variations corresponding to 4σ. The stringency of this condition varies depending on variations of a device, the stringency of the activation timing of a sense amplifier, a required operating voltage range, etc. In this case, a memory cell connected to a worst sense amplifier is arbitrarily selected again after a worst cell in which a defect occurs is once removed, and therefore the probability that a worst cell is encountered again corresponds to 5σ. Thus, the probability that repair is successful is about one millionth, which is practically sufficient. It is possible to provide more stringent design margins to memory cells and sense amplifiers, thereby increasing the speed and reducing the area.

This technique cannot repair fabrication defects, but has an advantage that the redundant circuit 141 of FIG. 27 is not required, and therefore, an increase in area can be reduced or prevented even if the number of repaired portions is increased. Also, compared to the technique of repairing a high-resistive defect by changing the order of selection of address decoders only in the page mode as in the technique described in Patent Document 3, in this technique attention is paid to a different problem, i.e., random variations, and measures can be taken for random access memory macros without impairing random access capability.

As a technique of ensuring the reliability of LSIs, there is a conventional burn-in test in which the LSI is aged under high-temperature and high-voltage conditions to screen out defective products. Burn-in is typically performed under high-voltage conditions, and therefore, the LSI often operates properly even if a transistor characteristic varies slightly. Note that after burn-in, defective operation (hereinafter referred to as a burn-in defect) often occurs at a normal voltage, particularly at the lower limit of a recommended operating voltage, due to variations in a transistor characteristic, e.g., a degradation in negative bias temperature instability (NBTI), etc. For the burn-in defect, the redundancy repair scheme employing a redundant cell has disadvantages that data stored in the redundant cell during burn-in cannot be arbitrarily changed, or a data change circuit is required in a redundant cell portion in order to change data in the burn-in mode. The technique of the present disclosure does not have such disadvantages, and has an advantage that burn-in stress can be applied to change stored data to 0 and 1 alternately.

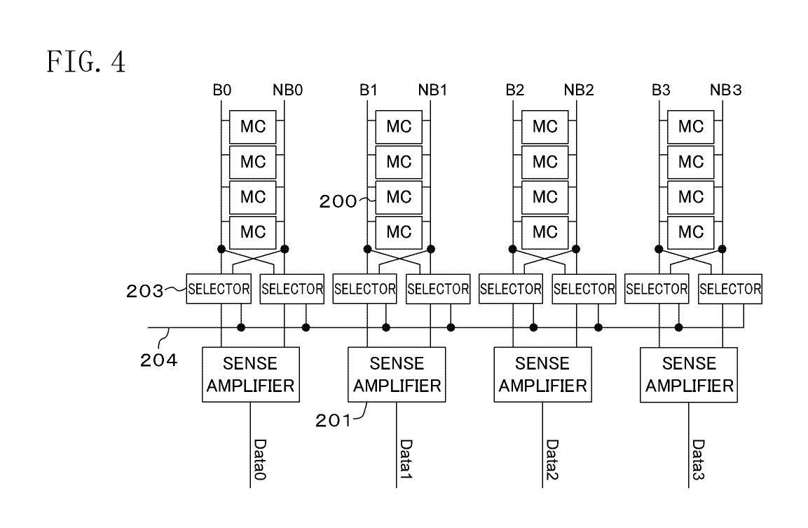

Note that the control signal 204 (-207) of the selector 203 may be separately controlled for each column as shown in FIG. 1, or may be shared in a macro as shown in FIG. 4.

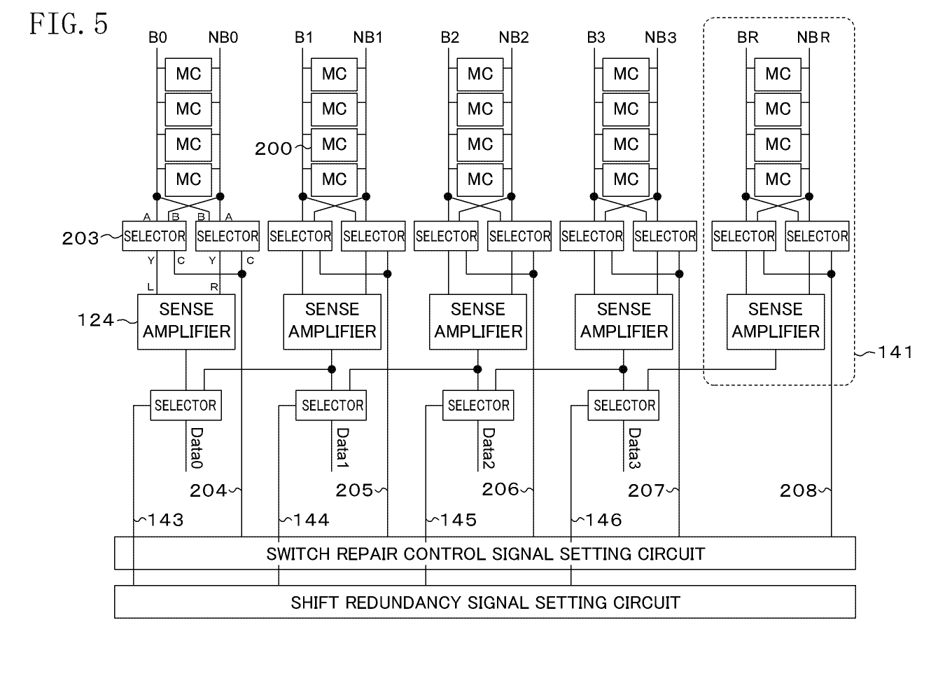

As shown in FIG. 5, the present disclosure can be used in combination with a conventional redundancy repair scheme employing a redundant circuit, which is mainly directed to repair of fabrication defects. A circuit can be configured so that the positive-phase and negative-phase inputs of bit lines to sense amplifiers including those for the memory cells of a redundant circuit 141 can be changed based on the selector control signals 204-208. As a result, both fabrication defects and defective characteristics can be effectively repaired, where the defective characteristics are repaired or corrected by the present disclosure.

The defective read speed of cells often occurs due to a low voltage. Therefore, in actual use, cells may be initially tested at a typical voltage, and fabrication defects of cells may be repaired using a conventional redundancy repair circuit employing a redundant circuit, and thereafter, defects found by a test at the lower limit of an operating voltage are repaired by the switch repair technique of the present disclosure.

A control signal for a repaired circuit determined by an LSI test may be stored in a fuse element, which does not lose information even in the absence of power supply. As a result, even after shipment of the LSI, desired repaired circuit settings are obtained every time the LSI is turned on. Note that the present disclosure is not limited to this. For example, instead of storing repair data in a fuse element, an LSI may be repaired using a built-in self test and redundancy (BISR) system every time the LSI is turned on.

In the switch repair technique of the present disclosure, the positive and negative phases of bit lines are switched at a portion where repair is performed. In this case, read data would be inverted without any further process. To avoid this, a fuse signal may be read out in a logic circuit outside a macro, and only when the repaired portion is accessed, the positive or negative logic of data may be inverted. More preferably, the data level is corrected in a macro, and in this case, the chip can be designed more easily.

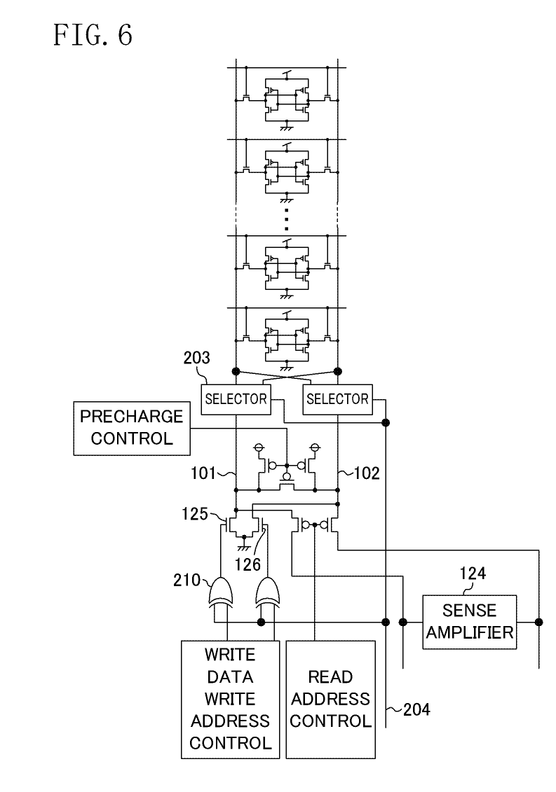

There are two techniques of solving the above problem. In a first technique, as shown in FIG. 6, a write data inversion circuit 210 which inverts input write data in association with a switch repair control signal 204 is built in a macro, whereby write data is inverted at a portion where the repair technique of the present disclosure is performed. In this technique, a complicated process, such as a process of inverting data based on a repair address outside a macro, etc., is not required, and the positive or negative logic of read data can be corrected in the macro. Moreover, a circuit portion for reading memory cells is not involved in calculation of a logic circuit related to the present disclosure, resulting in an advantage that the access time is not increased.

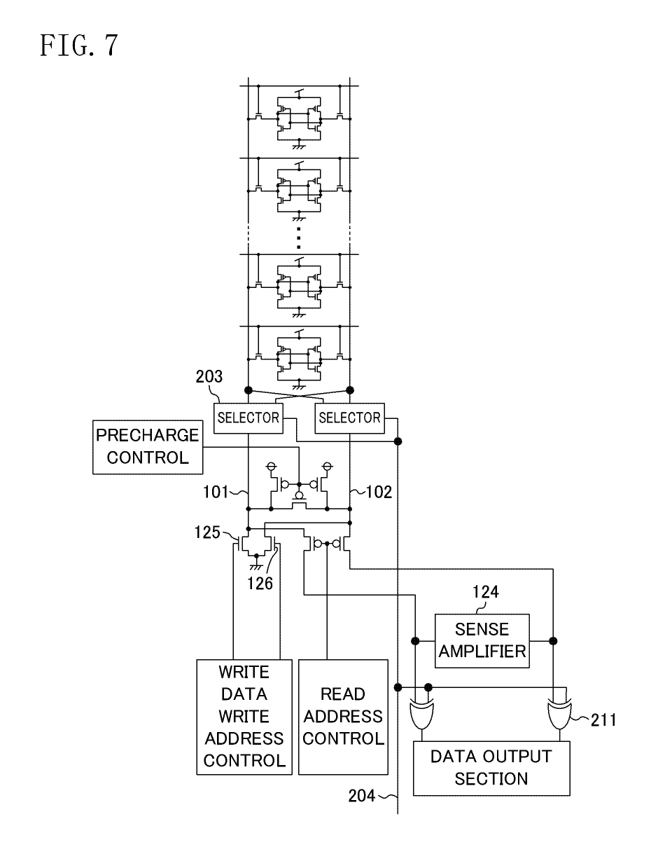

In a second technique, as shown in FIG. 7, a read data inversion circuit 211 which inverts read data in association with a switch repair control signal 204 is built in a macro in a read path. This technique has an advantage that data stored in cells in a memory test pattern is invariable before and after repair. The first technique has a disadvantage that when a checker pattern is externally applied, the relationship between the potentials (0 or 1) of adjacent cells is changed at a portion where write data is inverted, so that the checker pattern which provides a bias relationship of different potentials does not provide different potentials. By contrast, the second technique does not have such a disadvantage. When it is desired to test an LSI exactly in accordance with an application pattern, a circuit needs to be much complicatedly adapted, i.e., a test pattern is modified based on trimming information in a built-in self test (BIST) circuit to support the repair technique of the present disclosure. In some cases, a test can be performed using other patterns, such as an all-zero pattern, an all-one pattern, etc., instead of the checker pattern. However, when it is desired to perform a test in accordance with an application pattern and, in addition, under constraints on the process of addressing rows/columns etc., the inversion of output data of FIG. 7 is effective.

### Second Embodiment

In the first embodiment, characteristic repair is performed by changing only the connection relationship between the positive and negative phases of bit lines while the relationship between a memory cell column and a sense amplifier corresponding to each other is kept unchanged. Alternatively, the combination itself of a memory cell column and a sense amplifier may be changed, whereby switch repair can still be performed.

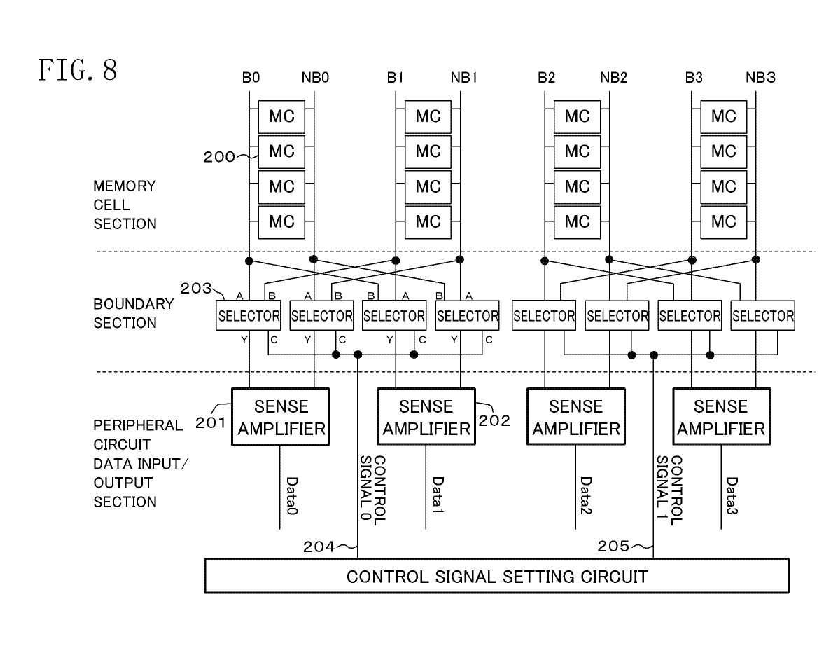

FIG. 8 shows an image circuit diagram of a second embodiment. Each selector 203 outputs A to Y when C=high and B to Y when C=low. Selector control signals 204 and 205 are normally set to C=high, and an input side A is normally selected. Therefore, in FIG. 8, a memory cell and a sense amplifier which are vertically arranged and aligned normally correspond to each other. It is now assumed that defective read speed caused by an insufficient cell current occurs in the relationship between a memory cell 200 and a sense amplifier 201 which are located in the leftmost column. In this case, an external fuse is trimmed to set a control signal 0 (204) to be low. As a result, memory cells in the second column from the left are connected to the first sense amplifier 201 from the left, and memory cells in the leftmost column are connected to the second sense amplifier 202 from the left. As a result, the combination of the worst memory cell 200 and the worst sense amplifier 201 is canceled, whereby a defective characteristic caused by insufficient read speed is avoided.

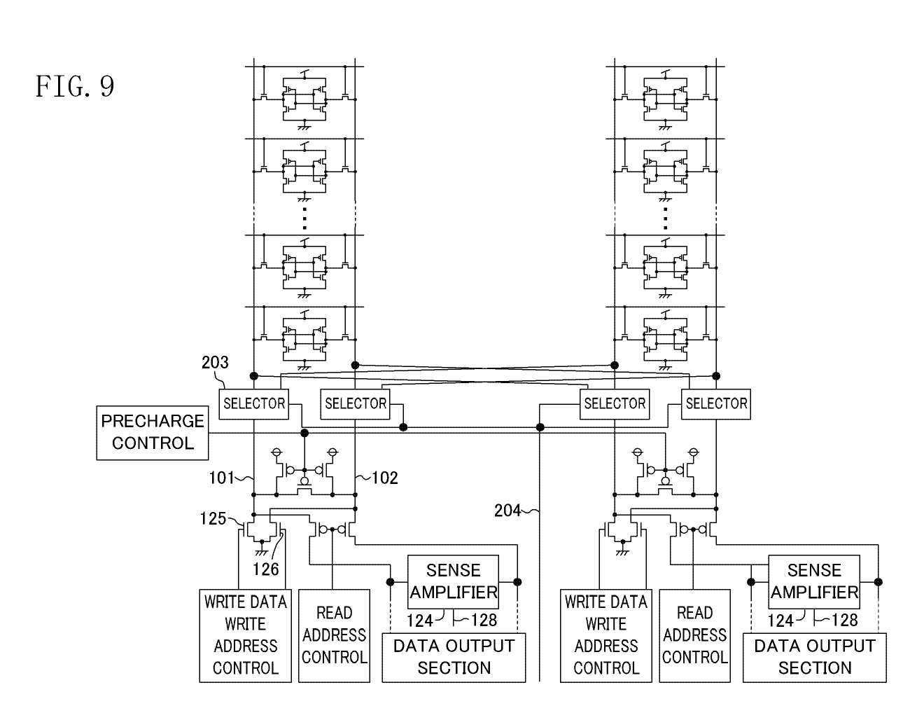

FIG. 9 shows a circuit diagram including a write system. As can be seen from the circuit diagram, if the characteristic repair of the present disclosure is performed by switching only memory cell columns while the relationship between the positive and negative phases of memory cells corresponding to a data input/output section is kept unchanged, the write system or the read system does not require the data inversion process.

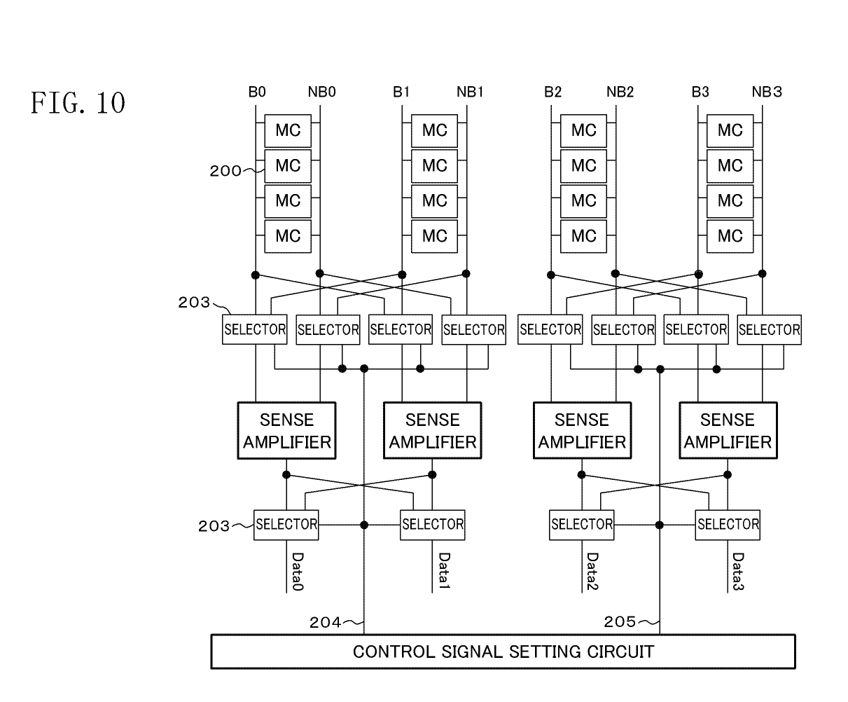

In the present disclosure, not all components of data input/output sections need to be switched. As shown in FIG. 10, only a sense amplifier may be switched to that of another data input/output section. Although not shown, other components as well as sense amplifiers on which switch repair is performed do not need to be adjacent to each other, or alternatively, a plurality of components may be switched in a cyclic manner.

According to the present disclosure, characteristic repair can be performed on a defective characteristic caused by random variations by replacing combinations of components. As in the first embodiment, advantages that random access operation can be supported, a redundant circuit is not required, there is not a problem with burn-in stress, etc., can be obtained.

### Third Embodiment

The first and second embodiments provide example techniques of repairing a defective characteristic, such as insufficient speed etc., caused by the relationship between a memory cell having a small cell current and a sense amplifier having a large offset. The switch repair of the present disclosure is also effective to the erroneous read problem which occurs in the single bit line read scheme, which is described in the BACKGROUND section. In a third embodiment, an example in which the switch repair of the present disclosure is applied to the erroneous read problem will be described. For reference, even in the single bit line scheme, defective read speed occurs due to the relationship between a memory cell having a small cell current and a local amplifier having variations in logic threshold which are adverse to speed, and can be repaired or corrected by the switch repair technique of the present disclosure.

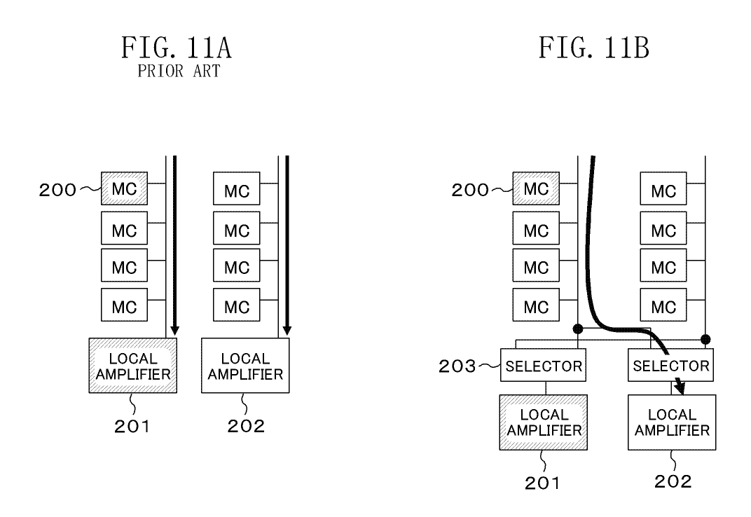

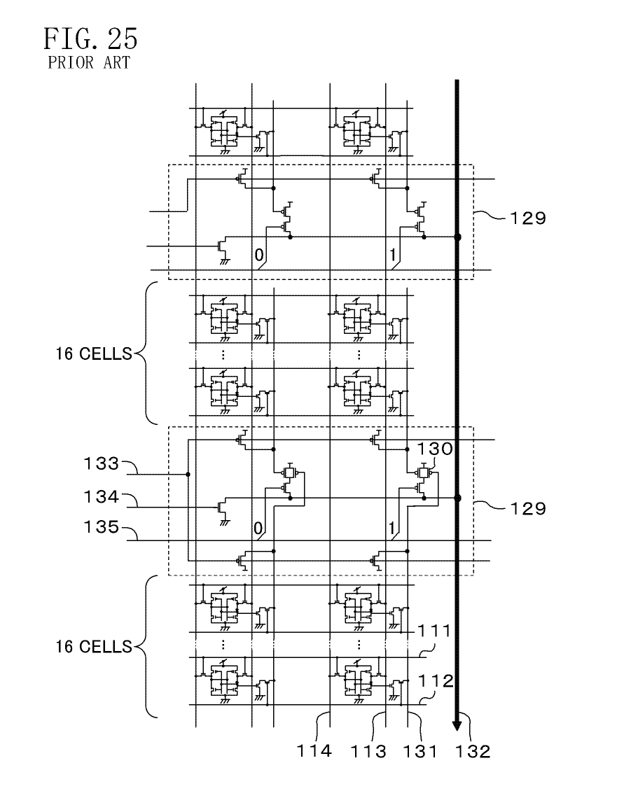

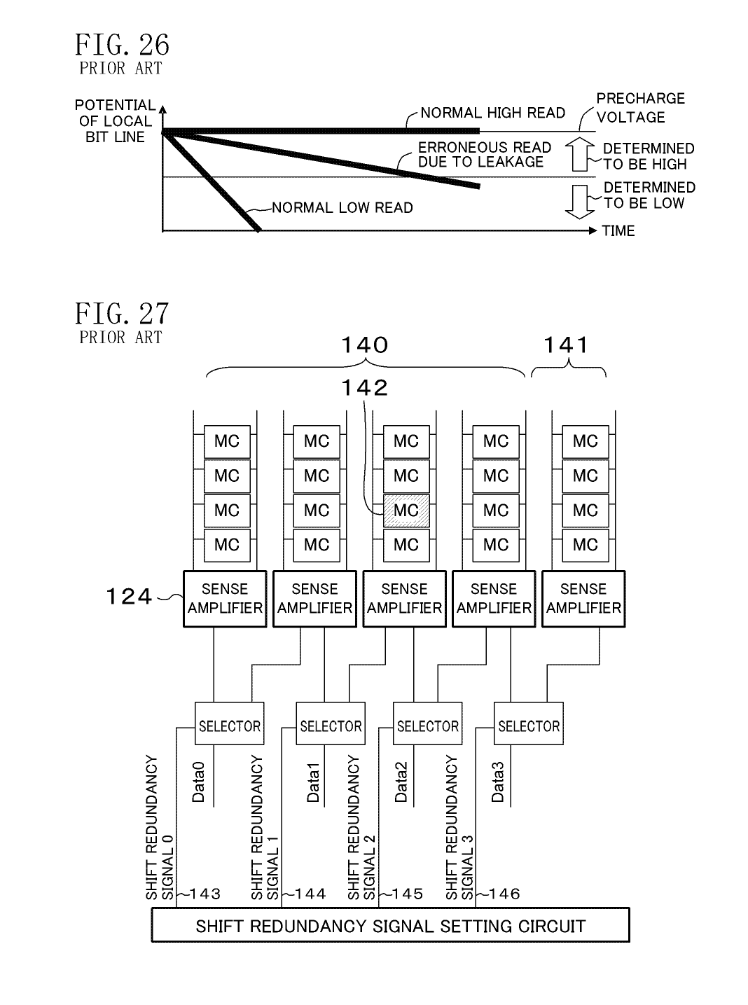

As shown in FIG. 25, the single read bit line structure includes the local amplifier 129 which receives a local bit line at the gate of the PMOS transistor 130. In this case, in the worst amplifier 201 (FIG. 11A), the Vt of the access transistor (122 of FIG. 22) at the read port of a memory cell is low, so that a large leakage current occurs, and the logic threshold of the local amplifier 129 varies toward the VDD precharge level, and therefore, erroneous read operation occurs. When read operation and write operation are simultaneously performed at two ports, an erroneous read current is further superimposed by occurrence of a weak on state caused by floating of an internal latch node. This erroneous read operation can be corrected by, as shown in a conceptual diagram of FIG. 11B, inserting selectors 203 to modify the relationship between a worst cell 200 and a worst local amplifier 201 using the switch repair technique.

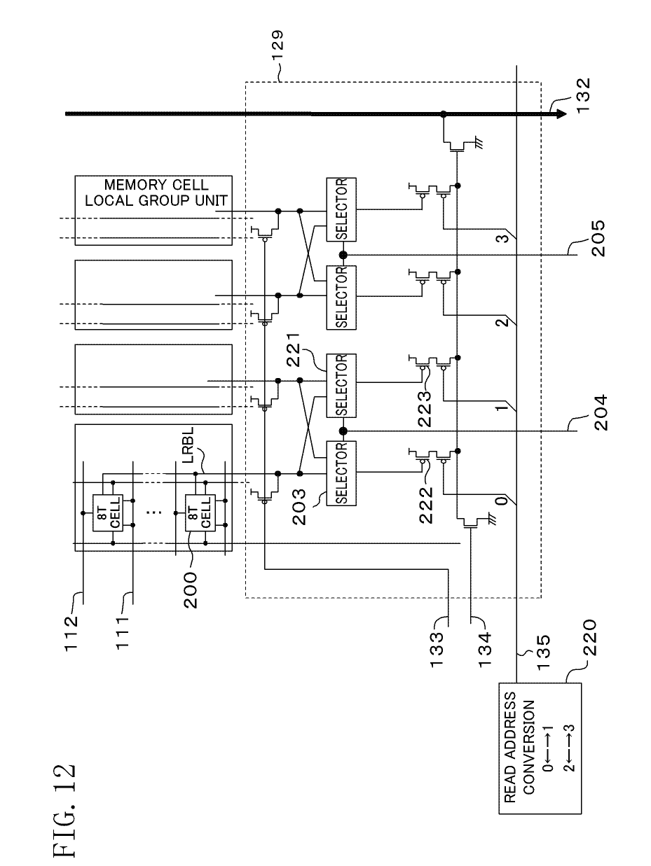

FIG. 12 is a circuit diagram mainly showing a local amplifier section in a four-column arrangement having a local read bit line (LRBL) in each column. When a worst cell 200 has a large erroneous read leakage current, the Vt of a receiver PMOS transistor 222 is low, and the logic threshold of the local amplifier varies at a higher level, erroneous read operation occurs. Here, settings of a selector control signal 204 are changed by fuse trimming, and the selector 203 is changed to a selector 221 for the PMOS transistor of a local amplifier corresponding to a column in which the worst cell 200 exists. Connection is switched from the low-Vt PMOS transistor 222 having a worst Vt to the PMOS transistor 223 having an average Vt which is expected not to be worst in terms of normal distribution. In this case, at the same time, a read address conversion circuit 220 converts a read address 135 by trimming so that the correspondence relationship of the read address 135 is kept in a logic address generation process of the read address 135. In other words, the logic address relationship between 0 and 1 or between 2 and 3 of a column address signal is reversed, corresponding to the selector switch process.

In the example of FIG. 12, the column address signal 135 which is supplied to and shared by other bits existing along the word line direction is also changed, so that the column switch signal 204 in a macro needs to be shared by bits in the macro. Note that this portion can be separately controlled if the logic circuit design of the local amplifier 129 is changed, and depends on detailed circuit design.

If the read bit lines have a hierarchical bit line structure, the capacity of the local bit line is reduced, so that erroneous read operation is likely to occur, and therefore, the benefit of the present disclosure is large.

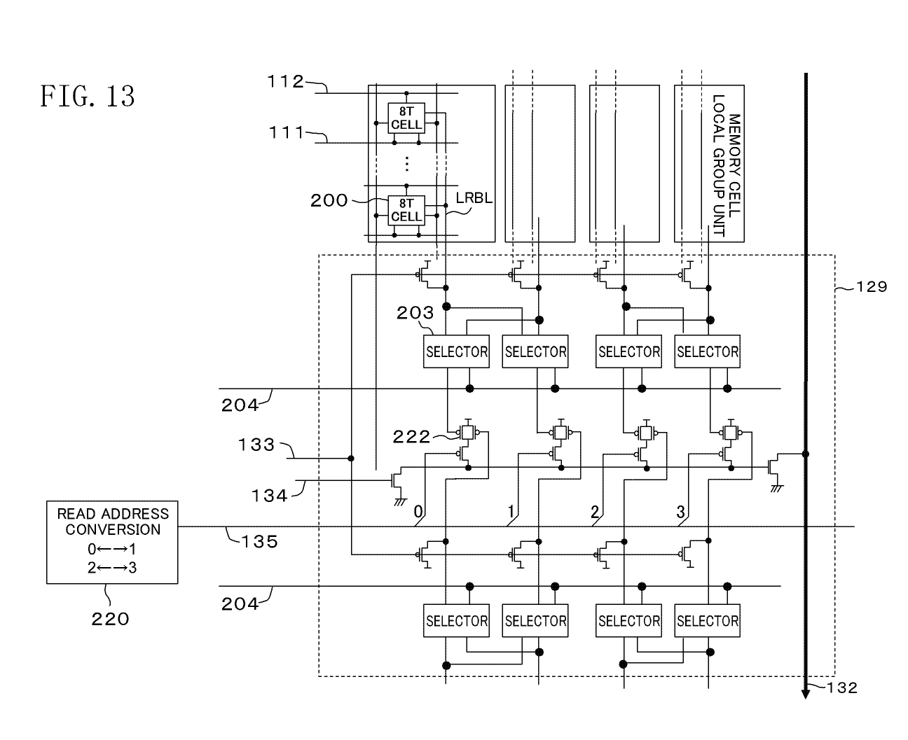

In the case of the hierarchical bit line structure, the memory region is divided along the bit line direction. Therefore, as shown in FIG. 13, even if a control is performed on a local amplifier-by-local amplifier basis by passing an all-column-switch signal along a single horizontal line, only regions divided by the local amplifier section 129 in the memory cell area are switched, so that the probability that a new defect occurs due to the switching is low. Thus, the area of control signal lines and calculation elements which have a hierarchical bit line structure and are used to perform a control in columns separately, is reduced, whereby the present disclosure can be efficiently applied.

### Fourth Embodiment

In the fourth embodiment, a characteristic repair technique related to an assist circuit which improves a read/write characteristic of a memory cell will be described.

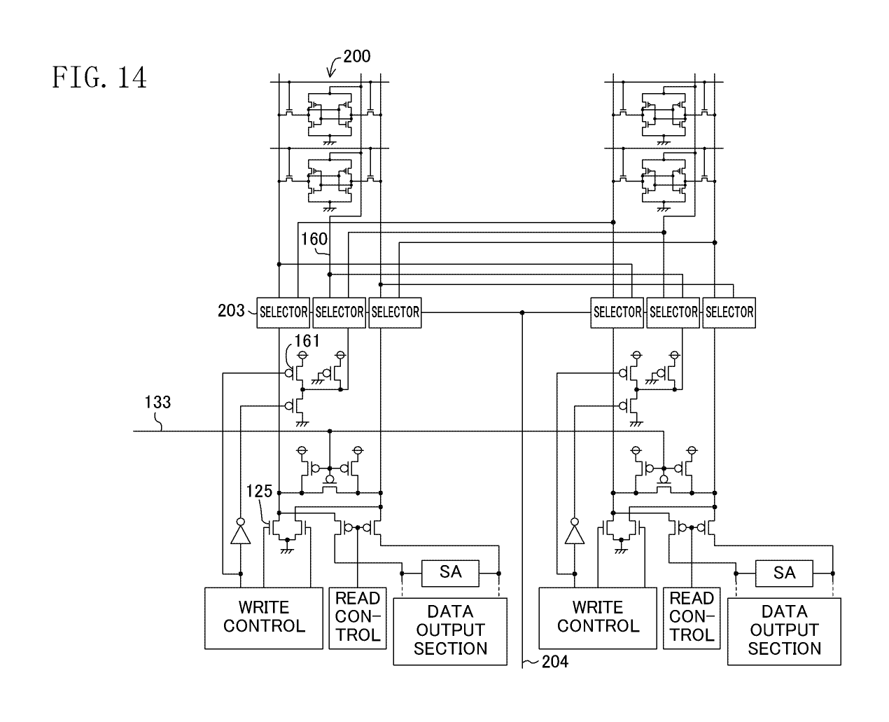

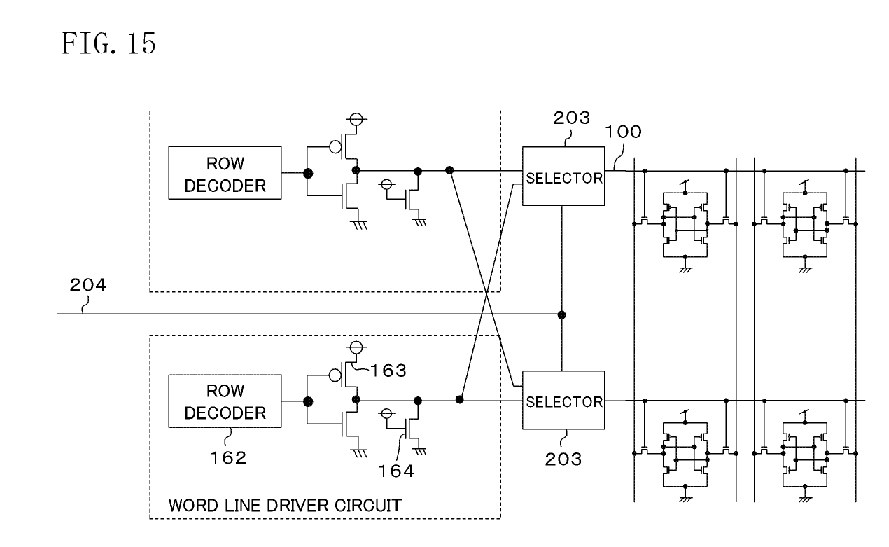

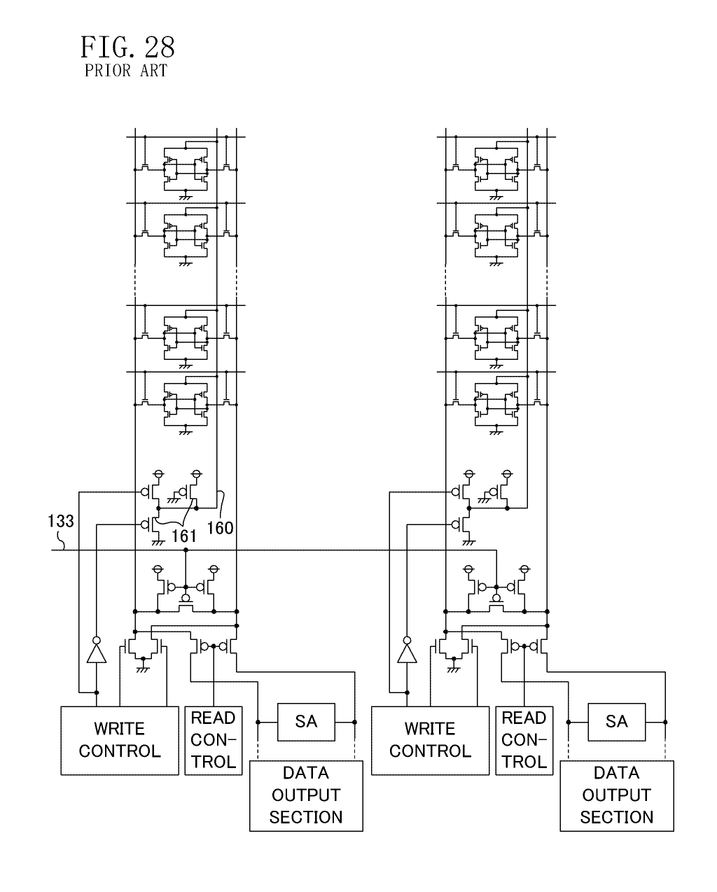

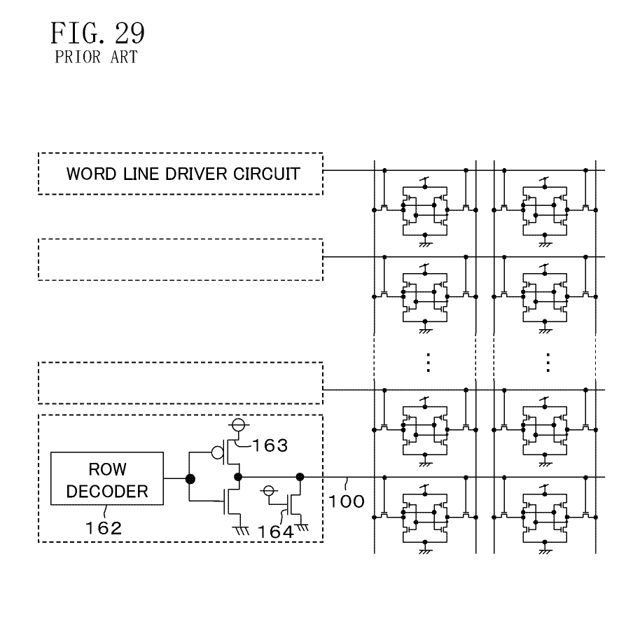

As described in the BACKGROUND section, there is a write assist circuit (see FIG. 28) which improves a write characteristic by decreasing the latch potential of a memory cell during write operation. There is also a read assist circuit (see FIG. 29) which improves the data hold level (static noise margin) of a memory cell by decreasing the high level of an activated word line to reduce the performance of an access transistor. In these example circuit diagrams, i.e., both examples of FIGS. 28 and 29, intermediate potentials of a plurality of competitive transistors in the on state are used to obtain a potential required for cell characteristic assist operation. However, because the transistor size of a peripheral circuit increases with the progress of miniaturization, the level of variations in the intermediate potential also increases with the progress of miniaturization. Both the variations in assist potential and the variations in memory cell characteristic tend to increase with the progress of miniaturization, and therefore, a cell defective characteristic, such as erroneous write operation, an insufficient noise margin during read operation, etc., is more likely to occur. To solve this problem, in the present disclosure, switch repair of FIG. 14 is performed on the write assist circuit of FIG. 28, and switch repair of FIG. 15 is performed on the read assist circuit of FIG. 29.

In FIG. 14, in a normal state, the first memory column from the left corresponds to a data input/output section including a write assist potential generation circuit of interest. When a defect occurs, the state of a selector 203 is changed based on a control signal 204 so that the second memory cell column from the left is caused to correspond to the data input/output section.

When attention is paid only to the assist potential variations of VDDM, a circuit configuration in which only assist potentials are switched may be provided instead of this example in which bit lines are also switched. When the entire data input/output section is included as in this example of FIG. 14, the present disclosure is applicable to a case where a write buffer 125 has an insufficient ability to discharge to a low potential due to variations, in addition to the variations in assist potential.

FIG. 15 shows an example in which the present disclosure is applied to a read assist circuit. The level of a word line 100 may decrease with respect to a cell which is difficult to write or may increase with respect to a cell having a small noise margin, due to random variations of a peripheral circuit section and a memory cell section. In this case, by changing the select state of a selector 203 based on a control signal 204, the relationship between memory cells corresponding to a row decoder 162 is vertically switched. As a result, erroneous write operation or an insufficient noise margin caused by both the variations in memory cell and the variations in word line level is repaired or corrected.

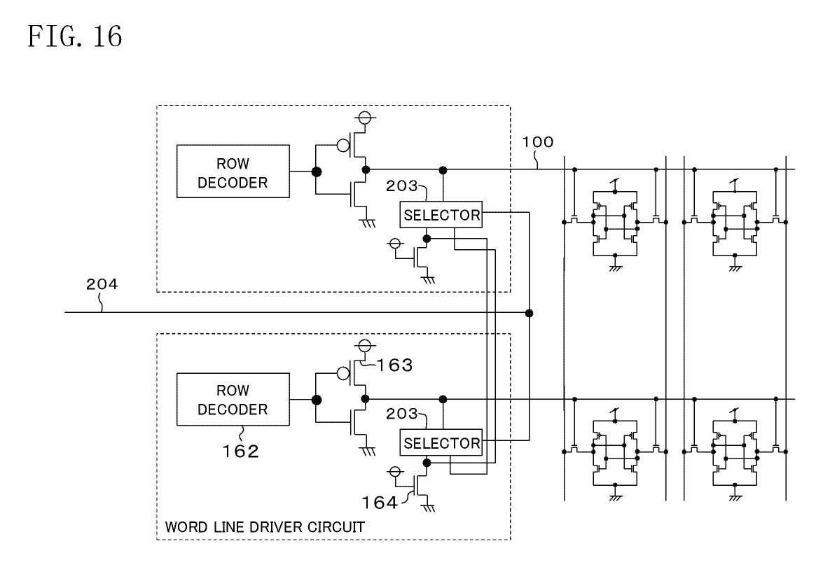

As shown in FIG. 16, there is a scheme in which only the connection relationship between small transistors which are used to slightly decrease the potential of a word line is switched between adjacent parts. A pull-down transistor 164 is a transistor which has a large on-state resistance in order to slightly decrease the potential of a word line 100, i.e., has a small gate width. Therefore, the ability to decrease the potential of the word line 100 varies significantly due to the influence of random variations. To solve this problem, a selector 203 having a relatively great on-state resistance is used to switch pull-down transistors 164 having a small gate width which are vertically adjacent to each other. Compared to the scheme of FIG. 15, the scheme of FIG. 16 has advantages that a bit map of memory cells is invariable before and after repair, and the word line 100 can be driven at high speed because a selector does not intervene the word line buffer section.

Any configuration of FIGS. 14, 15, and 16 has advantages that a defective characteristic which occurs when the relationship between variations of an assist circuit and a memory cell is worst can be repaired or corrected, and a redundant cell and a redundant peripheral circuit are not used, the area is small, and random access capability is not impaired.

### Fifth Embodiment

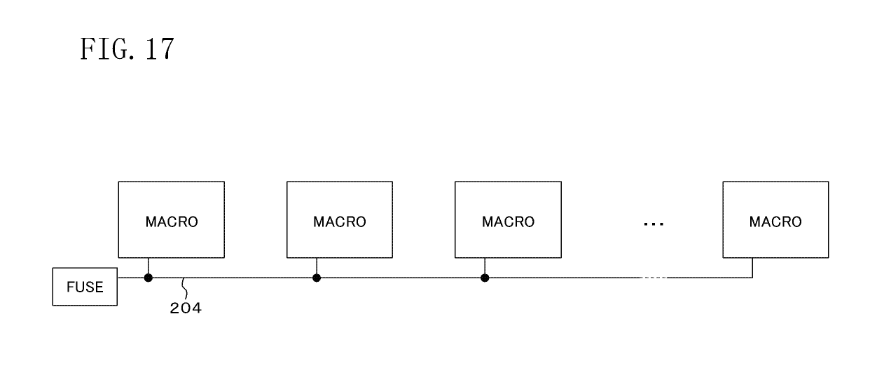

Finally, a fifth embodiment of the present disclosure related to a configuration of a repair control signal on a chip, which is preferable when the first to fourth embodiments are carried out, will be described. For example, in the case of the configuration of the first embodiment of FIG. 4, as shown in FIG. 17, if a fuse element which stores repair data is shared by all macros on a chip, all combinations are switched, and therefore, even after the characteristic repair of the present disclosure is performed, the probability that a defective characteristic occurs again increases.

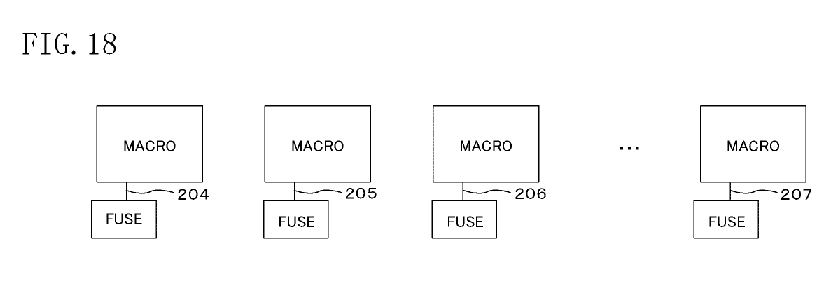

In contrast to this, if a fuse element is provided for each macro separately as shown in FIG. 18, a control signal for a defective macro specified by a test, i.e., only one of control signals 204-207 of FIG. 18, is controlled to perform component switch for characteristic repair only on the macro. Therefore, compared to the configuration of FIG. 17, a rate at which a defective product is successfully repaired can be increased.

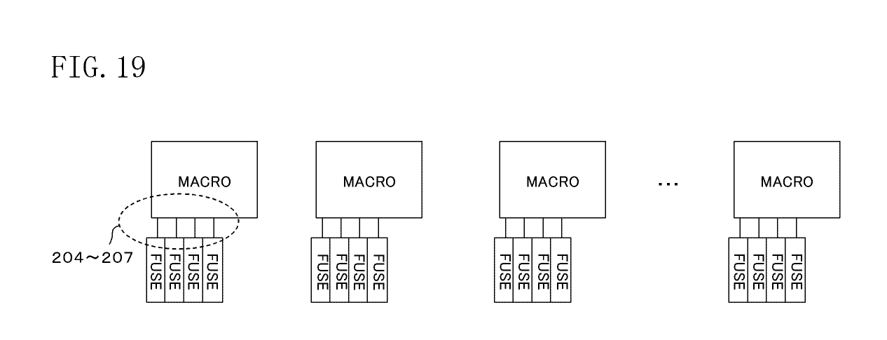

Moreover, as shown in FIG. 19, in the case of a circuit configuration in which separate columns can be repaired as shown in FIG. 1, a plurality of signals are input, the signals are decoded, and a column on which switch repair is performed is limited in a macro. The macro is configured so that, as shown in FIG. 1, switch repair can be performed on a plurality of columns separately. Because a configuration recombination region during switch repair is limited, the probability that a defect occurs in a different portion after switch repair can be reduced.

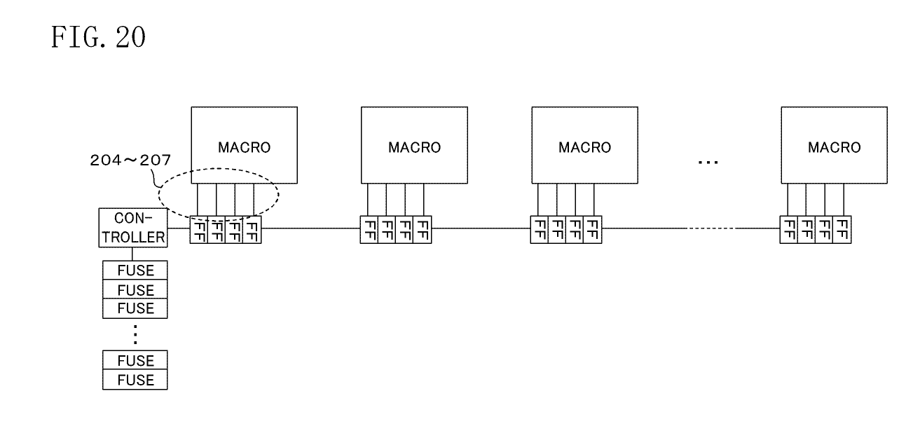

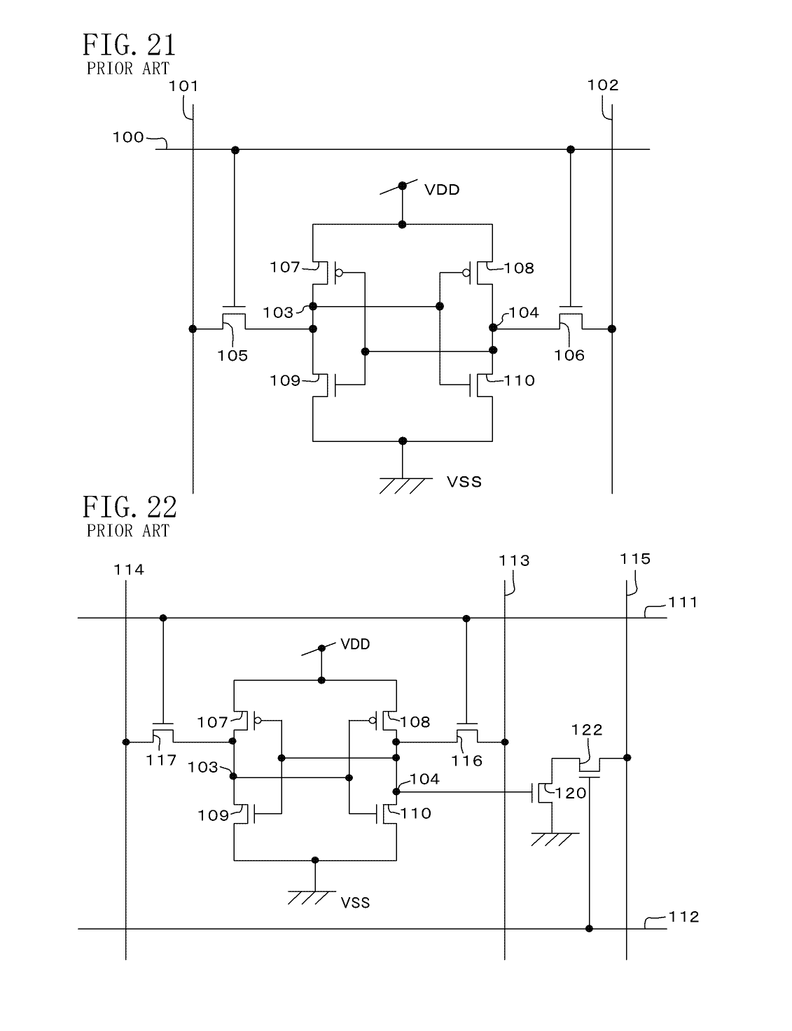

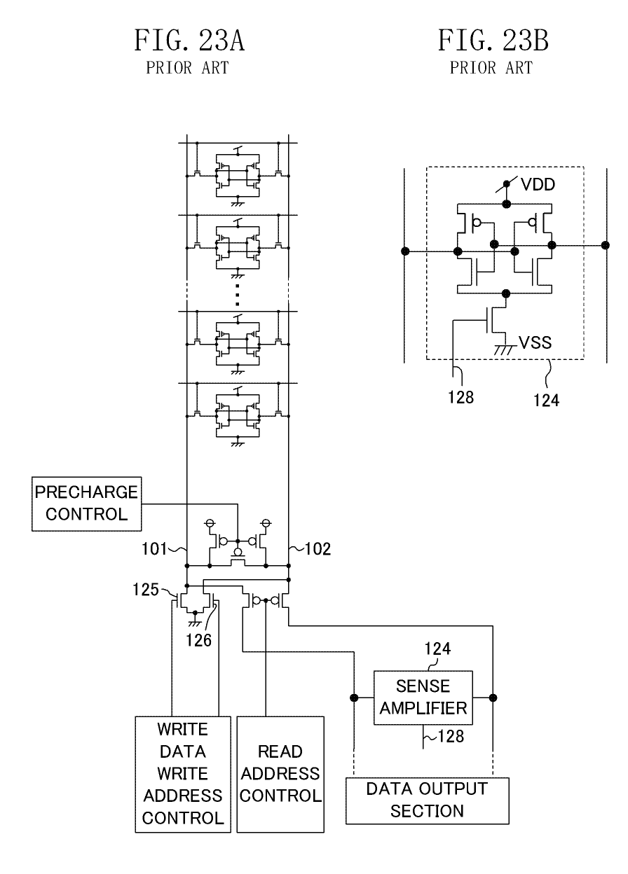

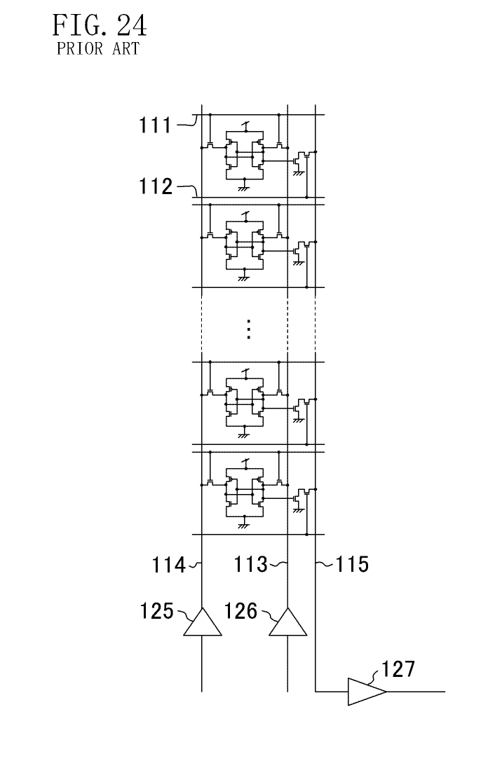

As shown in FIG. 20, a control signal may be supplied to a macro after the control signal is temporarily supplied from a fuse element to a flip-flop (FF) by scan operation. In this scheme, a smaller number of fuse elements may be required, so that the area of the fuse elements may be reduced.

Although SRAMs have been mainly described as an example semiconductor memory device, the present disclosure is not limited to SRAMs. The present disclosure is applicable to other memory devices, such as dynamic random access memory (DRAM) devices, read-only memory (ROM) devices, etc. The present disclosure is not limited to single-port memory devices, and is also applicable to multiport memory devices.

The present disclosure provides a characteristic repair technique useful particularly for a reduction in area, higher-speed operation, and a reduction or prevention of erroneous read operation against random variations in microfabrication processes, in semiconductor memory devices. The present disclosure is applicable to ROMs, DRAMs, etc. in addition to SRAMs.

What is claimed is:

1. A semiconductor memory device comprising:
a memory cell;
a differential sense amplifier having a first input and a second input;
a positive-phase bit line and a negative-phase bit line connected to the memory cell;
a first selector circuit configured to select and output one of the positive-phase and negative-phase bit lines to the first input of the differential sense amplifier, based on a control signal; and
a second selector circuit configured to select and output the other of the positive-phase and negative-phase bit lines to the second input of the differential sense amplifier, based on the control signal,
wherein
the output of the first selector circuit and the output of the second selector circuit are complementary to each other.

2. The semiconductor memory device of claim 1, further comprising:
a circuit configured to invert write data to the memory cell based on the control signal.

3. The semiconductor memory device of claim 1, further comprising:
a circuit configured to invert data output from the differential sense amplifier based on the control signal.

4. A semiconductor memory device comprising:
a plurality of memory cells;
a plurality of peripheral circuits; and
a selector circuit configured to electrically connect any of the plurality of memory cells to any of the plurality of peripheral circuits,
wherein
an electrical connection relationship between any of the plurality of memory cells and any of the plurality of peripheral circuits is changed based on a control signal for controlling the selector circuit.

5. The semiconductor memory device of claim 4, wherein
the plurality of peripheral circuits are a circuit including a differential sense amplifier.

6. The semiconductor memory device of claim 4, wherein
the plurality of memory cells are of a single bit line read type.

7. The semiconductor memory device of claim 6, further comprising:
a hierarchical bit line structure.

8. The semiconductor memory device of claim 4, wherein
the plurality of peripheral circuits are a source potential supply circuit for a memory cell latch inverter.

9. The semiconductor memory device of claim 4, wherein
the plurality of peripheral circuits are a word line driver circuit.

10. The semiconductor memory device of claim 1, further comprising:
a non-volatile element configured to set select states of the first and second selector circuits.

11. The semiconductor memory device of claim 4, further comprising:
a non-volatile element configured to set a select state of the selector circuit.

12. The semiconductor memory device of claim 1, wherein
only a single input pin configured to control the first and second selector circuits is provided for each macro.

13. The semiconductor memory device of claim 4, wherein
only a single input pin configured to control the selector circuit is provided for each macro.

14. The semiconductor memory device of claim 1, wherein
a plurality of input pins configured to control the first and second selector circuits are provided for each macro.

15. The semiconductor memory device of claim 4, wherein
a plurality of input pins configured to control the selector circuit are provided for each macro.
